(19) United States
(12) Patent Application Publication
(10) Pub. No.: US 2021/0234035 A1
(43) Pub. Date: Jul. 29, 2021

(54) TRANSISTOR MANUFACTURING METHOD AND GATE-ALL-AROUND DEVICE STRUCTURE

(71) Applicant: Ningbo Semiconductor International Corporation (Shanghai Branch), Shanghai (CN)

(72) Inventor: Xiaoshan QIN, Ningbo (CN)

(21) Appl. No.: 17/210,917

(22) Filed: Mar. 24, 2021

Related U.S. Application Data
(63) Continuation of application No. PCT/CN2019/117797, filed on Nov. 13, 2019.

(30) Foreign Application Priority Data
Dec. 26, 2018 (CN) 201811602315.8

(51) Int. Cl. H01L 29/78; H01L 21/3105; H01L 21/311; H01L 21/28; H01L 29/66

(52) U.S. Cl. CPC H01L 29/785; H01L 21/31055; H01L 2029/7858; H01L 21/28194; H01L 29/66795; H01L 21/31111

(57) ABSTRACT

A method for forming a transistor includes providing a base substrate, the base substrate including a lower substrate, an upper substrate, and an insulating layer in between; forming a source region and a drain region in the upper substrate, and a channel region in between; forming, on both sides of the channel region, holes penetrating the upper substrate in a direction perpendicular to the surface of the upper substrate; forming a cavity by removing, from the holes, a portion of the insulating layer under both of the holes and the channel region; and forming a gate structure to cover the upper surface of the channel region and the sidewall surfaces of the holes and the cavity close to the channel region. The cavity is connected to both holes, and the gate structure includes a gate dielectric layer and a gate electrode on the gate dielectric layer.

### CROSS-REFERENCE TO RELATED APPLICATIONS

This application is a continuation application of PCT patent application No. PCT/CN2019/117797, filed on Nov. 13, 2019, which claims the priority of Chinese patent application No. 201811602315.8, filed on Dec. 26, 2018, the entire content of which is incorporated herein by reference.

### FIELD OF THE DISCLOSURE

The present disclosure generally relates to the field of semiconductor fabrication technology and, more particularly, relates to a transistor manufacturing method and a gate-all-around (GAA) device structure.

### BACKGROUND

The channel of a metal-oxide-semiconductor (MOS) transistor can have a high breakdown voltage and a high resistive current (I_{ds}). When the channel length is increased, the breakdown voltage can be increased, but the Ids current will be reduced. In order to overcome this contradiction, in existing technology, the upper gate dielectric layer and the upper gate electrode are first formed on the upper surface of the channel region, and then the back gate dielectric layer and the back gate electrode are formed on the lower surface of the channel region. This structure is called a dual-gate electrode structure, which requires two gate dielectric layers to be grown, and the manufacturing process is complicated, resulting in lower productivity, thereby not conducive to mass production of devices.

Therefore, there is a need to provide a semiconductor structure based on a silicon-on-insulator (SOI) substrate and gate-all-around (GAA) device structure, and a manufacturing method thereof that is simplified and convenient for mass production.

### BRIEF SUMMARY OF THE DISCLOSURE

One aspect of the present disclosure provides a method for forming a transistor. The method includes providing a base substrate, the base substrate including a lower substrate, an insulating layer, and an upper substrate. The insulating layer is disposed between the lower substrate and the upper substrate. The method further includes forming a source region and a drain region in the upper substrate, and a channel region between the source region and the drain region. In a plane parallel to the surface of the upper substrate, the direction from the source region to the drain region is a first direction, and the direction perpendicular to the first direction is a second direction. The method also includes forming, on both sides of the channel region along the second direction, holes penetrating the upper substrate along a third direction perpendicular to the first direction and the second direction; forming a cavity by removing, from the holes, a portion of the insulating layer under both of the holes and the channel region; and forming a gate structure to cover the upper surface of the channel region and the sidewall surfaces of the holes and the cavity close to the channel region. The cavity is connected to both holes, and the gate structure includes a gate dielectric layer and a gate electrode on the gate dielectric layer.

Another aspect of the present disclosure provides a gate-all-around (GAA) device structure, the GAA device structure includes a base substrate, including a lower substrate, an insulating layer, and an upper substrate. The insulating layer is disposed between the lower substrate and the upper substrate. The GAA device structure further includes a source region and a drain region formed in the upper substrate, and a channel region formed between the source region and the drain region. Holes are formed on both sides of the channel region and penetrating the upper substrate. A cavity, connected to both of the holes, is formed under the channel region. The GAA device structure also includes a gate structure formed on an upper surface of the channel region and sidewall surfaces of the holes and the cavity close to the channel region.

Other aspects of the present disclosure can be understood by those skilled in the art in light of the description, the claims, and the drawings of the present disclosure.

### BRIEF DESCRIPTION OF THE DRAWINGS

Through more detailed descriptions of various exemplary embodiments of the present disclosure with reference to the accompanying drawings, the above and other objectives, features, and advantages of the present disclosure will become more apparent. In the exemplary embodiments of the present disclosure, the same reference numerals generally represent the same components.

FIG. 1 illustrates a schematic flowchart of an exemplary method for manufacturing a transistor according to various embodiments of the present disclosure;

FIG. 2 illustrates a schematic top view of an exemplary gate-all-around device structure according to various embodiments of the present disclosure; and

FIGS. 3A-3E illustrate schematic diagrams of a gate-all-around device structure along an A-A direction at different stages according to various embodiments of the present disclosure.

### DETAILED DESCRIPTION

The present disclosure will be described in more detail below with reference to the accompanying drawings. Although some embodiments of the present disclosure are shown in the drawings, it should be understood that the present disclosure can be implemented in various forms and should not be limited by the embodiments set forth herein. On the contrary, these embodiments are provided to make the present disclosure more thorough and complete, and to fully convey the scope of the present disclosure to those skilled in the art.

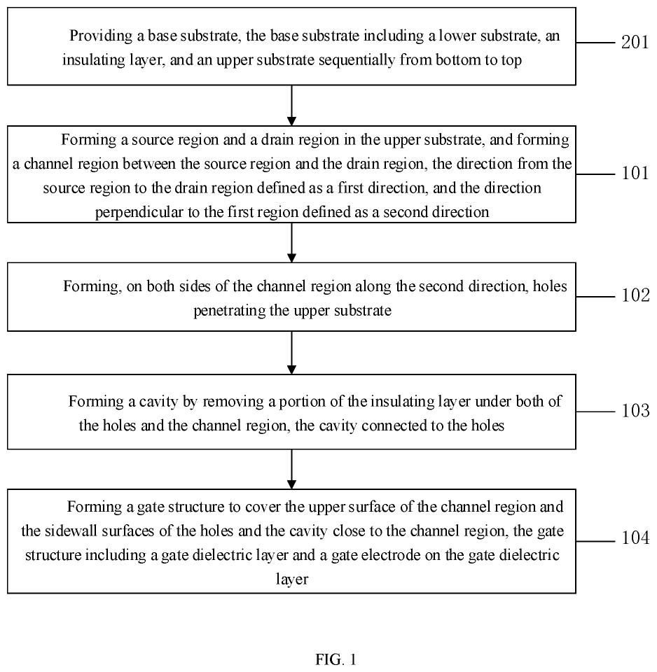

As shown in FIG. 1, according to the manufacturing method of a transistor consistent with a first exemplary embodiment of the present disclosure, the manufacturing method may include the following exemplary steps.

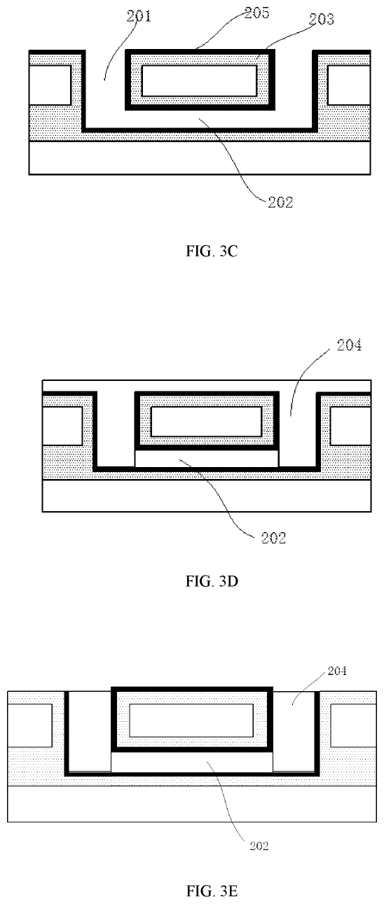

In step 1, as shown in FIG. 3A, a base substrate may be provided. The base substrate may include a lower substrate 101, an insulating layer 102, and an upper substrate 103 sequentially from bottom to top.

For example, the base substrate may be a silicon-on-insulator (SOI) substrate. The formation method of the SOI substrate may include: in a first step, performing thermal oxidation on the upper surface of the lower substrate 101 at a room-temperature environment to form a silicon oxide insulating layer, and injecting a certain dose of hydrogen ions into the insulating layer 102; in a second step, bonding the lower substrate 101 and the upper substrate 103 under normal temperature conditions; in a third step, performing low-temperature annealing to make that the injected hydrogen ions form bubbles and strip off a portion of upper substrate 103 above the insulating layer 102, and then performing high-temperature annealing to enhance the bonding strength between the unstripped upper substrate 103 and the lower substrate 101; and in a fourth step, planarizing the surface of the unstripped upper substrate 103.

A stress initiation region may be formed in the lower substrate 101 under the insulating layer 102 through the method of ion implantation, annealing, and stripping. The stress initiation region may provide favorable stress for the channel region 201 of the semiconductor device manufactured in the upper substrate 103, and may be conducive to improving the performance of the semiconductor device. The stress initiation region may be formed in the lower substrate 101 and extend into the upper substrate 103. The upper plane of the stress initiation region may not be higher than the lower plane of the insulating layer 102.

As an example, referring to FIG. 3A, a silicon nitride (SiNₓ) dielectric layer, which serves as a mask material, may be formed on the oxide layer of the upper substrate 103, and a pattern may be transferred to the silicon nitride dielectric layer using photolithography technology to form a patterned mask layer 105 on the surface of the upper substrate 103.

As an example, the material of the insulating layer 102 may be crystalline or amorphous oxide, nitride, or any combination thereof. In one embodiment, silicon oxide (SiO₂) is selected.

As an example, the material of the upper substrate 103 and the lower substrate 101 may be single-crystalline silicon, germanium (Ge), or III-V group compound (such as SiC, gallium arsenide, indium arsenide, indium phosphide, etc.).

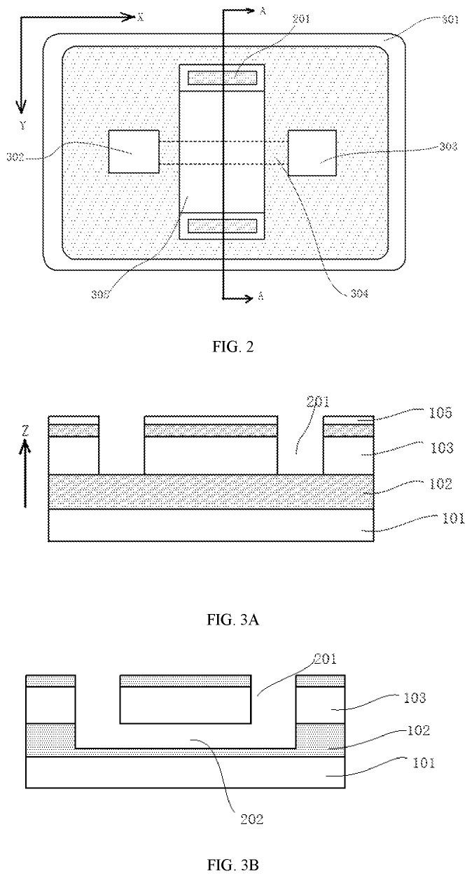

As indicated by the directions of the arrows shown in FIG. 2 and FIG. 3A, in step 2, a source region 302 and a drain region 303 may be formed in the upper substrate 103, a channel region 304 may be formed between the source region 302 and the drain region 303, the direction from the source region 302 to the drain region 303 may be a first direction X, and the direction perpendicular to the first direction X may be a second direction Y.

For example, the source region 302, the drain region 303, and the channel region 304 may be formed by a method including photolithography, ion implantation, diffusion, and/or other suitable processes.

In one embodiment, a photoresist pattern may be formed in the source region, the drain region, and the channel region by a photolithography process to cover and define the corresponding source region. The photoresist pattern may be used as an etching mask to etch the exposed portion of the silicon layer, and then the used photoresist pattern may be removed. Further, P-type or N-type dopants or impurities may be injected into the source region and the drain region of the upper substrate 103. Then, a laser annealing, flash annealing, or other process may be used to activate the dopants in the source/drain extension region. A variety of processing methods in existing technology may be adopted for forming the source region, the drain region, and the channel region.

In step 3, as indicated by the directions of the arrows shown in FIG. 2, FIG. 3A, and FIG. 3B, on each of the two sides of the channel region 304 along the second direction Y, a hole 201 may be formed through the upper substrate 103 along a third direction Z perpendicular to the first direction X and the second direction Y. The insulating layer 102 under the holes 201 and under the channel region may be etched from the holes 201 to form a cavity 202. The cavity 202 may be connected to the hole 201.

In one embodiment, the method of forming the holes 201 may include: forming a patterned mask layer 105 on the surface of the base substrate to define the position of each hole 201; and etching the base substrate using the patterned mask layer 105 as a mask to form the holes 201.

Referring to FIG. 3A, as an example, the hole 201 may be formed by dry etching. First, a photoresist film layer may be coated on the surface of the base substrate, and ultraviolet (UV) light may be used to irradiate the photoresist film layer through a mask and thus cause a chemical reaction of the photoresist in the exposed region. Then, the photoresist in the exposed or unexposed region may be dissolved and removed by developing technology (the former is called positive photoresist, and the latter is called negative photoresist), so that the pattern on the mask may be copied to the photoresist film layer. The pattern may be transferred to the base substrate using etching technology, such that a patterned mask layer 105 may be formed on the surface of the base substrate, and the position of each hole 201 may also be defined. Further, an etch opening may be defined on the mask layer 105 to expose the portion where the opening is to be formed, while the portion where no opening needs to be formed may be protected. The base substrate may be etched by an etchant using the patterned mask layer 105 as a mask to form the holes 201.

In one embodiment, referring to FIG. 3B, the method of forming the cavity 202 may include: etching the insulating layer 102 using the patterned mask layer 105 as a mask to form the cavity 202.

In one embodiment, the insulating layer 102 may be made of silicon oxide.

In one embodiment, the etching process may be a wet etching process or a dry etching process.

As an example, continuing the reference to FIG. 3B, the cavity may be etched by a wet etching process. Because of the unique property of hydrogen fluoride (HF), e.g., only etching the silicon dioxide insulating layer without etching other materials, an HF solution may be injected into the holes 201 to etch the portion of silicon dioxide exposed in the holes 201. The insulating layer 102 may be etched both horizontally and vertically to form a cavity 202 under the channel region. The solution adopted may have a concentration of approximately 10% to 20% and an etching rate may be approximately 1000 Å/min.

In step 4, referring to FIG. 2 and FIG. 3C, a gate structure may be formed, and the gate structure may cover the upper surface of the channel region 304. The holes 201 on the two sides of the channel region 304 and the cavity 202 below may expose the sidewalls on both sides of the lower part of the channel region 304, so that a gate-all-around (GAA) structure may be formed on both sides and the upper and lower surfaces of the channel region 304. The gate structure may include a gate dielectric layer 203 and a gate electrode 305 covering the gate dielectric layer 203. Through the GAA structure, the channel-control ability of the gate electrode 305 may be improved, and the breakdown voltage may be increased. At the same time, the current Ids may be increased, and the growth process of the gate insulating layer of the MOS transistor may be simplified.

Continuing the reference to FIG. 2 and FIG. 3C, in one embodiment, the method for forming the gate electrode 305 may include: forming a gate electrode layer 205 on the surface of the gate dielectric layer 203; and patterning the gate electrode layer 205 to form the gate electrode 305.

In one embodiment, the gate dielectric layer 203 may include an oxide layer.

In one embodiment, through thermal oxidation or atomic layer deposition (ALD), an oxide layer may be formed as the gate dielectric layer 203.

As an example, referring to FIG. 3 and FIG. 3C, forming the GAA structure on both sides and the upper and lower surfaces of the channel region 304 may include: using a thermal growth method to form an oxide layer on both sides and the upper and lower surfaces of the channel region 304. For example, the thermal growth method may be first used to oxidize both sides and the upper and lower surfaces of the channel region 304 to form silicon oxide, and the silicon oxide may be used as the gate dielectric layer 203. Because of the existence of the hole 201 and the cavity 202, the channel region 304 may be an exposed region. Through a single thermal growth, an oxide layer may be formed on both sides and the upper and lower surfaces of the channel region 304. The thickness of the oxide layer may be in a range of approximately 1 nm to 10 nm.

In one embodiment, as shown in FIG. 3C, an oxide layer containing a high-k gate dielectric material may also be formed by ALD. The high-k gate dielectric material may be able to increase the physical thickness of the gate dielectric layer 203 while ensuring the proportional relationship of various electrical parameters, thereby reducing gate leakage current and improving device reliability.

In one embodiment, as shown in FIG. 2 and FIG. 3C, polycrystalline silicon may be deposited on the surface of the gate dielectric layer 203 to form the gate electrode layer 205. For example, through vapor deposition, a layer of polycrystalline silicon may be deposited on the side surface of each hole 201 and the side surface of the cavity 202, and polycrystalline silicon may also be deposited on the upper surface of the channel region 304.

In one embodiment, a metal gate electrode may be deposited on the side surface of the hole 201 and the side surface of the cavity 202 through ALD. The metal gate electrode may not need to be doped in-situ to form a gate electrode contact region.

In one embodiment, the thickness of the polycrystalline silicon layer may be in a range of approximately 2.5 kÅA to 3 kÅ.

In step 5, the method may further include when the material of the gate electrode is polycrystalline silicon, the gate electrode layer 205 may be doped in-situ to form a gate electrode contact region.

For example, referring to FIG. 3C, after the gate electrode layer 205 is formed, an annealing process may be performed to control the doping profile of the gate electrode layer 205 to adjust the turn-on voltage of the device.

In one embodiment, referring to FIG. 3C, the semiconductor structure may be annealed by an instant annealing process, for example, laser annealing at a high temperature of approximately 800° C. to 1100° C. The annealing process may also be able to repair damages to the upper substrate 103, the insulating layer 102, and the lower substrate 101 caused by the implantation process.

In step 6, the method may also include metalizing the top surface of the gate electrode 305 to form a metal silicide.

For example, the metal silicide may be generated through metallization reaction in the gate electrode contact region to reduce the resistance of the device.

The metallization reaction may first use a method such as physical sputtering to deposit a metal on the wafer, and then through a first annealing process at a lower temperature (600° C. to 700° C.) and then a second annealing process at a higher temperature (800° C. to 900° C.), make the metal (Cu, Ti, Co, NiPt, etc.) react with the directly contacted active region and the silicon of the polycrystalline-silicon gate electrode to form a metal silicide and thus reduce the contact resistance of the gate electrode.

In step 7, referring to FIG. 3D, after forming the gate structure, the method may further include filling the hole 201 with an insulating material 204.

For example, a physical vapor deposition (PVD) or chemical vapor deposition (CVD) method may be adopted to deposit the insulating material 204 such as silicon oxide, silicon nitride, etc.

In step 9, referring to FIG. 2, FIG. 3D, and FIG. 3E, the portion of the gate electrode layer 205 outside of the boundary of the channel region 304 together with the insulating material 204 deposited on the surface may be removed, and the portion of the insulating material 204 deposited on the top of the gate electrode 305 may be removed to expose the gate electrode 305.

In one embodiment, referring to FIG. 2, FIG. 3D, and FIG. 3E, the excess portion of the gate electrode layer 205 outside of the boundary of the channel region 304 together with the insulating material 204 deposited on the surface may be removed through an etching process. At the same time, the portion of the insulating material 204 deposited on the top of the gate electrode 305 may also be removed through etching to expose the gate electrode 305.

Referring to FIGS. 2-3E, according to the gate-all-around (GAA) device structure consistent with a second embodiment of the present disclosure, the GAA device structure may include:

A source region 302 and a drain region 303 formed in an upper substrate 103 of a base substrate 301, and a channel region 304 formed between the source region 302 and the drain region 303; a hole 201 formed on each side of the channel region 304 and penetrating the upper substrate 103; a cavity 202 formed under the channel region 304, both holes 201 connected with the cavity 202; a gate structure formed on the upper surface of the channel region 304 and the sidewall surfaces of the holes 201 and the cavity 202 that are close to the channel region 304.

In one embodiment, the gate structure may include a gate dielectric layer 203 and a gate electrode 305 covering the gate dielectric layer 203. The gate electrode 305 may be made of polycrystalline silicon.

In one embodiment, the GAA device structure may further include a metal silicide formed on the top surface of the gate electrode 305.

In one embodiment, the hole may be filled with an insulating material.

Through the GAA structure, the channel-control ability of the gate electrode may be improved, and the breakdown voltage may be increased. At the same time, the current I_{ds} may be increased, and the growth process of the gate insulating layer of the MOS transistor may be simplified, which is convenient for mass production.

Compared with existing GAA device structure and transistor manufacturing method, the disclosed GAA device structure and transistor manufacturing method may demonstrate the following exemplary advantages.

According to the disclosed GAA device structure and transistor manufacturing method, holes are formed on both sides of the channel region of the SOI silicon top layer, and a cavity connecting with the holes is formed below the channel region. A GAA structure is formed on the upper and the lower surfaces and both sides of the channel region. Through the GAA structure, the ability of the gate in controlling the channel is increased, the breakdown voltage is improved, and at the same time, the current Ids is increased. As such, the growth process of the gate insulating layer of MOS transistors is simplified, which facilitates mass production.

The embodiments of the present disclosure have been described above, the above description is exemplary, not exhaustive, and is not limited to the disclosed embodiments. Various modifications and changes, without departing from the scope and spirit of the described embodiments, are obvious to those of ordinary skill in the art.

What is claimed is:

1. A method for forming a transistor, comprising:
providing a base substrate, the base substrate including a lower substrate, an insulating layer, and an upper substrate, wherein the insulating layer is disposed between the lower substrate and the upper substrate;
forming a source region and a drain region in the upper substrate, and a channel region between the source region and the drain region, wherein in a plane parallel to a surface of the upper substrate, a direction from the source region to the drain region is a first direction, and a direction perpendicular to the first direction is a second direction;
forming, on both sides of the channel region along the second direction, holes penetrating the upper substrate along a third direction perpendicular to the first direction and the second direction;
forming a cavity by removing, from the holes, a portion of the insulating layer under both of the holes and the channel region, wherein the cavity is connected to both of the holes; and
forming a gate structure to cover an upper surface of the channel region and sidewall surfaces of the holes and the cavity close to the channel region, wherein the gate structure includes a gate dielectric layer and a gate electrode on the gate dielectric layer.

2. The method according to claim 1, wherein forming the holes on both sides of the channel region and penetrating the upper substrate includes:
forming a patterned mask layer on a surface of the base substrate to define positions of the holes; and
etching the base substrate using the patterned mask layer as a mask, thereby forming the holes.

3. The method according to claim 2, wherein forming the cavity by removing the portion of the insulating layer under both holes and under the channel region includes:
etching the insulating layer using the patterned mask layer as a mask to form the cavity.

4. The method according to claim 3, wherein:
etching the insulating layer includes dry etching, wet etching, or a combination thereof.

5. The method according to claim 3, wherein:
the insulating layer is made of a material including silicon oxide.

6. The method according to claim 4, wherein:
etching the insulating layer includes wet etching; and
a hydrogen fluoride (HF) solution with a concentration in a range of approximately 10% to 20% is used for wet etching.

7. The method according to claim 1, wherein:
the gate dielectric layer includes an oxide layer.

8. The method according to claim 7, wherein:
the oxide layer is formed by thermal oxidation or atomic layer deposition (ALD).

9. The method according to claim 1, wherein forming the gate electrode includes:
forming a gate electrode layer on a surface of the gate dielectric layer; and
patterning the gate electrode layer to form the gate electrode.

10. The method according to claim 9, wherein:
the gate electrode is made of a material including polycrystalline silicon or a metal.

11. The method according to claim 10, further including:
when the gate electrode is made of polycrystalline silicon, in-situ doping the gate electrode layer with P-type or N-type dopants.

12. The method according to claim 9, further including:
metallizing a top surface of the gate electrode to form a metal silicide.

13. The method according to claim 1, after forming the gate structure, further including:
filling the holes with an insulating material.

14. A gate-all-around (GAA) device structure, comprising:
a base substrate, including a lower substrate, an insulating layer, and an upper substrate, wherein the insulating layer is disposed between the lower substrate and the upper substrate;
a source region and a drain region formed in the upper substrate, and a channel region formed between the source region and the drain region, wherein holes are formed on both sides of the channel region and penetrating the upper substrate, and a cavity, connected to both of the holes, is formed under the channel region; and
a gate structure formed on an upper surface of the channel region and sidewall surfaces of the holes and the cavity close to the channel region.

15. The GAA device structure according to claim 14, wherein:
the gate structure includes a gate dielectric layer and a gate electrode on the gate dielectric layer.

16. The GAA device structure according to claim 14, wherein:
the gate electrode is made of a material including polycrystalline silicon or a metal;

17. The GAA device structure according to claim 15, further including:
a metal silicide formed on a top surface of the gate electrode.

18. The GAA device structure according to claim 14, wherein:
the holes are filled with an insulating material.

19. The GAA device structure according to claim 16, wherein:
when the gate electrode is made of polycrystalline silicon, the gate electrode is doped with P-type or N-type dopants.

20. The GAA device structure according to claim 15, wherein:
the gate dielectric layer includes an oxide layer.
